(19) United States
(12) Patent Application Publication
(10) Pub. No.: US 2012/0234262 A1
(43) Pub. Date: Sep. 20, 2012

(54) WATER HEATER HAVING BACKUP POWER SYSTEM

(75) Inventors: Chung-Chin Huang, Taichung (TW); Chin-Ying Huang, Taichung (TW); Hsin-Ming Huang, Taichung (TW); Hsing-Hsiung Huang, Taichung (TW)

(73) Assignee: GRAND MATE CO., LTD., TAICHUNG (TW)

(21) Appl. No.: 13/048,643

(22) Filed: Mar. 15, 2011

(51) Int. Cl. F24H 9/20; F24H 1/16; H01L 35/30

(52) U.S. Cl. 122/14.2; 136/205

(57) ABSTRACT

A water heater includes a case, in which a hot source, a cold source, a thermoelectric cooling chip, and a power requiring unit are provided. The thermoelectric cooling chip has a close loop with a hot junction adjacent to the hot source; and a cold junction adjacent to the cold source, that the thermoelectric cooling chip generates a current through the close loop when a temperature at the hot junction, is higher than a temperature at the cold junction. The power requiring unit is electrically connected to the close loop of the thermoelectric cooling chip; therefore, the power requiring unit may be driven by the power from the thermoelectric cooling chip, when the main power is low or off.

### BACKGROUND OF THE INVENTION

1. Field of the Invention

The present invention relates generally to a water heater, and more particularly, to a water heater with a backup power system to provide power, when the main power is off.

2. Description of the Related Art

For a water heater lighting the fire by discharge, battery is the main power of discharge to light the fire and supply the essential power of screen, electronic devices of the water heater. Some water heaters have a blower which is driven by the battery as well.

The durability of battery, is the key factor to how long the water heater can function normally. Based on practical knowledge and experience, we know that the batteries need to be replaced after some time, that user has to prepare batteries for backup at home all the time. In addition, the water heater will function abnormally when the battery is low, so then the water cannot be heated to the setting temperature. It can become troublesome to our lives.

### SUMMARY OF THE INVENTION

The primary objective of the present invention is to provide a water heater, which may transfer heat to electricity to allow the water heater to function normally, and prolong the battery's life.

According to the objective of the present invention, a water heater includes a case, in which a hot source, a cold source in the case, a thermoelectric cooling chip, and a power requiring unit. The thermoelectric cooling chip has a close loop with a hot junction adjacent to the hot source, and a cold junction adjacent to the cold source that, the thermoelectric cooling chip generates a current through the close loop, when a temperature at the hot junction is higher than a temperature at the cold junction. The power requiring unit is electrically connected to the close loop of the thermoelectric cooling chip, to be driven by the current from the thermoelectric cooling chip.

In an embodiment, the water heater further has a heating device and a water pipe to be heated by the heating device. The water pipe has a cooling section to form the cold source, a heating section to form the hot source, and the hot junction of the thermoelectric cooling chip, is close to the heating section of the water pipe, while the cold junction is close to the cooling section of the water pipe.

### BRIEF DESCRIPTION OF THE DRAWINGS

FIG. 1 is a front view of the water heater of a first preferred embodiment of the present invention;

FIG. 2 is a lateral view of the water heater of the first preferred embodiment of the present invention;

FIG. 3 is a sectional view of the thermoelectric cooling chip of the first preferred embodiment of the present invention;

FIG. 4 is a flow chart of the power supply of the first preferred embodiment of the present invention;

FIG. 5 is a flow chart of the power supply of a second preferred embodiment of the present invention;

FIG. 6 is a front view of the water heater of a third preferred embodiment of the present invention; and

FIG. 7 is a flow chart of the power supply of the third preferred embodiment of the present invention.

### DETAILED DESCRIPTION OF THE INVENTION

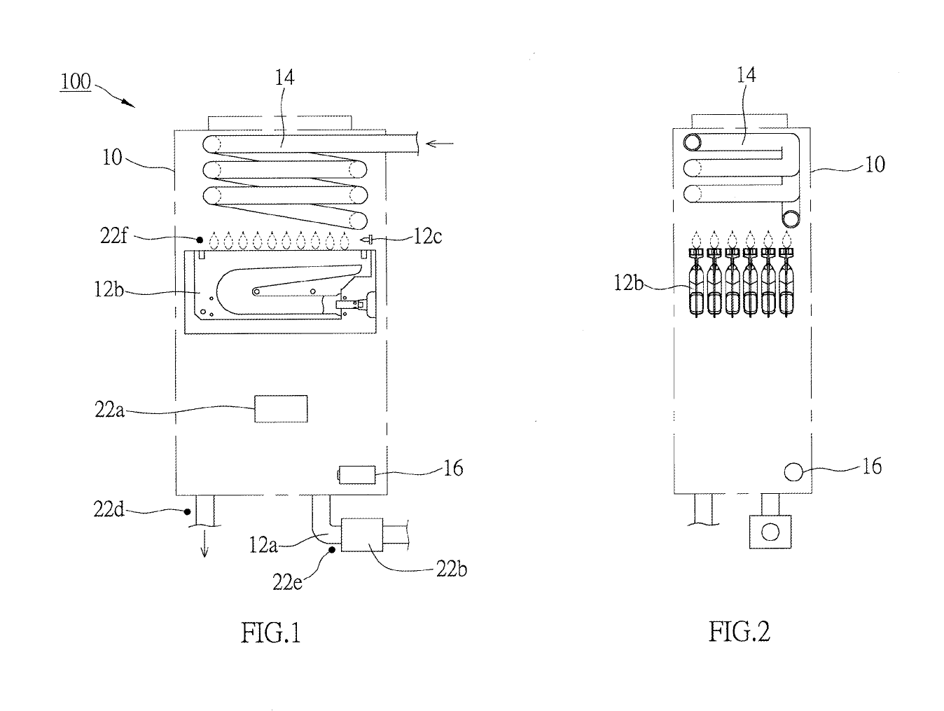

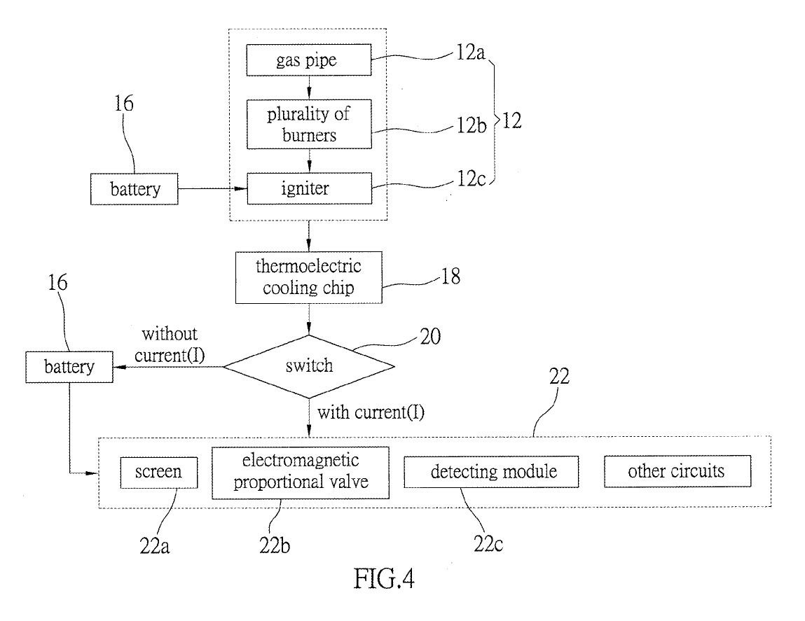

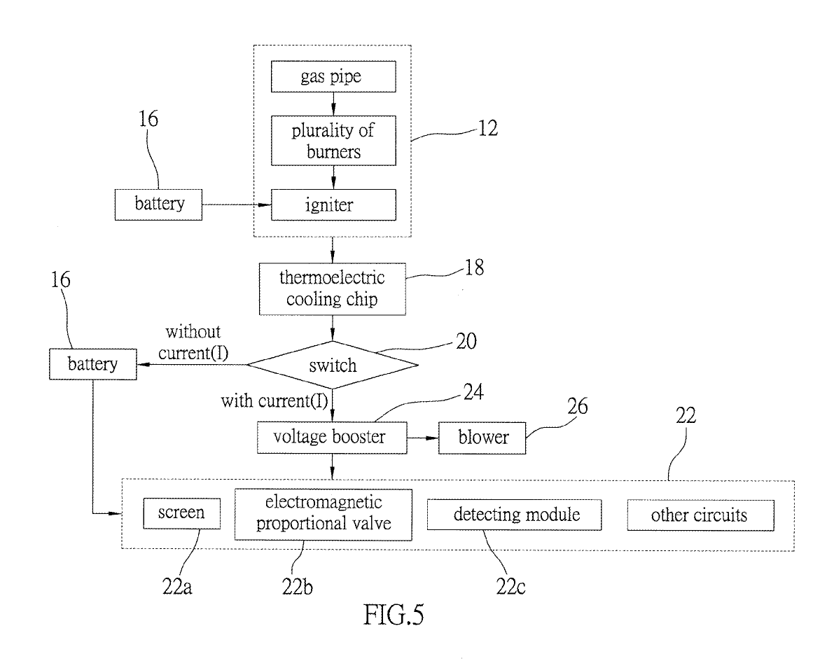

As shown in FIG. 1 to FIG. 4, a water heater 100 of the first preferred embodiment of the present invention includes a case 10, a heating device 12, a water pipe 14, a battery 16, a thermoelectric cooling chip 18, a switch 20, and power requiring unit 22.

The heating device 12 includes a gas pipe 12a, a plurality of burners 12b, and an igniter 12c. The gas pipe 12a is connected to a gas supply (not shown) to supply gas to the burners 12b, and the igniter 12c discharges to light the fire.

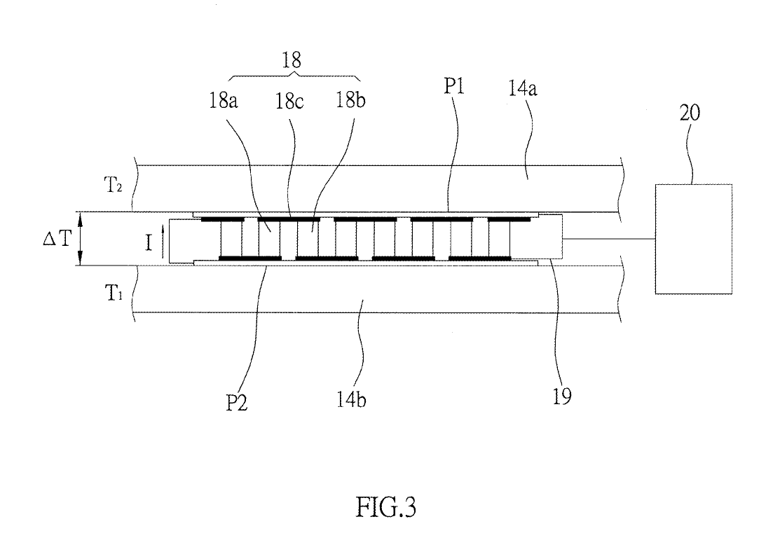

The water pipe 14 is a continuous S-shaped pipe mounted in the case 10, and above the heating device 12. The water pipe 14 has a cooling section 14a and a heating section 14b, as shown in FIG. 3. The cooling section 14a forms a cold source and the heating section 14b forms a hot source. The cold source and the hot source may act as other devices, with other functions for the water heater, for example, a fin may act as the cold source of the water heater. The battery 10 is mounted at a bottom of the case 10 to supply the igniter 12c, essential power for discharge.

The thermoelectric cooling chip 18 includes a plurality of n-type semiconductors 18a, and a plurality of p-type semiconductors 18b in an alternate arrangement. The neighboring n-type semiconductor 18a, and the p-type semiconductor 18b, are electrically connected through a conductive member 18c, to form a close loop 19. The conductive members 18c may be copper, aluminum, or other conductors. The close loop 19 has a cold junction P1 close to the cooling section 14a, and a hot junction P2, close to the heating section 14b. When a temperature T₁ at the hot junction P2 is higher than a temperature T₂ at the cold junction P1, i.e., a positive temperature difference (ΔT) between the hot junction P2, and the cold junction P1, the thermoelectric cooling chip 18 may generate a current I through the close loop 19.

The thermoelectric cooling chip 18 and the battery 16, are electrically connected to the power requiring unit 22 respectively, and the switch 20 is a switch of the battery 16, the thermoelectric cooling chip 18, and the power requiring unit 22. The switch 20 cuts off the connection between the battery 16 and the power requiring unit 22; and connects the thermoelectric cooling chip 18 to the power requiring unit 22, when the thermoelectric cooling chip 18 generate the current I to allow the thermoelectric cooling chip 18, to supply power to the power requiring unit 22. On the contrary, the switch 20 cuts off the connection between the thermoelectric cooling chip 18 and the power requiring unit 22, and connects the battery 16 to the power requiring unit 22, when the thermoelectric cooling chip 18 has no current to allow the battery 16 to supply power to the power requiring unit 22.

The power requiring unit includes at least an electronic device needing a low voltage such as a screen 22a on the case 10, an electromagnetic proportional valve 22b on the gas pipe 12a to control the gas flow, a detecting module 22c in the water heater, circuits, and other relative devices. The detecting module 22c includes a sensor 22d to read temperature of output water, a sensor 22e to read pressure in the gas pipe 12a, a sensor 22f to read the burners 12b, finding out whether or not, the burners 12b is functioning normally. In other words, the power requiring unit 22 may be working by power from the thermoelectric cooling chip 18 for a period of time when the water heater 100 is heating water, and when the battery is low or dead. For this reason, it prolongs the life of the battery, and the time to replace the battery, furthermore, it may support the igniter 12 to discharge normally, which may assist in maintaining constant water temperature.

Some types of water heaters on the market have a fin to extract the exhaust gas after they burn, and/or a blower to pump air into the water heater to help burning. Such devices need power with high voltage. The second preferred embodiment of the present invention provides a power supply system which may support such devices. As shown in FIG. 5, a voltage booster 24 is provided between the switch 20 and the power requiring unit 22, to increase an output voltage of the thermoelectric cooling chip 18 to a working voltage, which is the minimum voltage to activate a screen 22a, an electromagnetic proportional valve 22b, a detecting module 22c, and the blower 26.

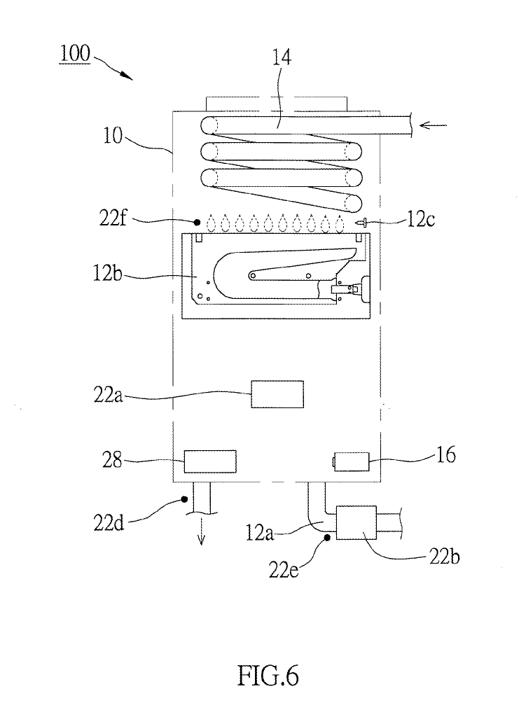

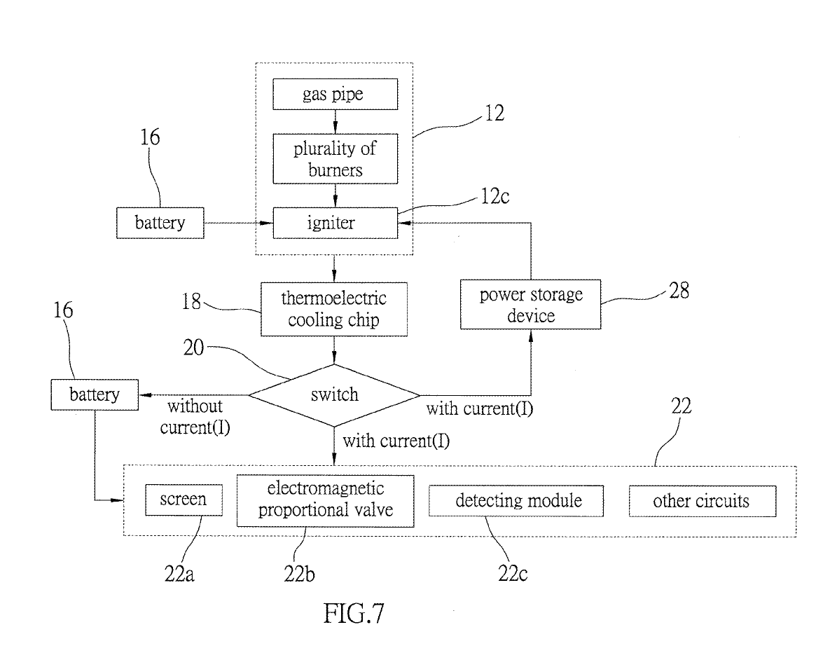

As shown in FIG. 6 and FIG. 7, a water heater of the third preferred embodiment of the present invention further provides a power storage device 28 on the bottom of the case 10, and connected to the thermoelectric cooling chip 18 to store the power generated by the thermoelectric cooling chip 18, that the power storage device 28 may supply power to the igniter 12c, to discharge and prolong the battery's life.

The description above is a few preferred embodiments of the present invention, and the equivalence of the present invention is still in the scope of claim construction of the present invention.

What is claimed is:

1. A water heater, comprising:
a case;
a hot source and a cold source in the case;
a thermoelectric cooling chip, which is mounted in the case, having a close loop with a hot junction adjacent to the hot source, and a cold junction adjacent to the cold source, that the thermoelectric cooling chip generates a current through the close loop when a temperature at the hot junction is higher, than a temperature at the cold junction; and
a power requiring unit electrically connected to the close loop of the thermoelectric cooling chip that the current is transmitted to the power requiring unit.

2. The water heater as defined in claim 1, further comprising a heating device and a water pipe to be heated by the heating device, wherein the water pipe has a cooling section to form the cold source, and a heating section to form the hot source, and the hot junction of the thermoelectric cooling chip is close to the heating section of the water pipe, and the cold junction is close to the cooling section of the water pipe.

3. The water heater as defined in claim 1, further comprising a switch between the thermoelectric cooling chip and the power requiring unit, to allow or cut off the current transmitted from the thermoelectric cooling chip to the power requiring unit.

4. The water heater as defined in claim 1, further comprising a voltage booster electrically connected to the thermoelectric cooling chip, to increase a voltage of the thermoelectric cooling chip to a working voltage.

5. The water heater as defined in claim 4, further comprising a power storage device electrically connected to the thermoelectric cooling chip.
